(19) United States
(12) Patent Application Publication
(10) Pub. No.: US 2026/0086453 A1
(43) Pub. Date: Mar. 26, 2026

(54) METHODS OF MANUFACTURING A NANOIMPRINT LITHOGRAPHY REPLICA MOLD, A NANOIMPRINT LITHOGRAPHY REPLICA, AND A SEMICONDUCTOR DEVICE

(71) Applicant: Taiwan Semiconductor Manufacturing Company, Ltd., Hsinchu (TW)

(72) Inventors: Yu-Luen DENG, Hsinchu (TW); Chih-Kai YANG, Hsinchu (TW); Hsin-Yuan LEE, Hsinchu (TW); Hsuan-Chin LU, Hsinchu (TW); Hua-Tai LIN, Hsinchu (TW); Ming-Feng SHIEH, Hsinchu (TW); Yu-Tien SHEN, Hsinchu (TW)

(73) Assignee: Taiwan Semiconductor Manufacturing Company, Ltd., Hsinchu (TW)

(21) Appl. No.: 19/036,561

(22) Filed: Jan. 24, 2025

Related U.S. Application Data
(60) Provisional application No. 63/698,327, filed on Sep. 24, 2024.

(51) Int. Cl. G03F 7/00; H01L 21/027

(52) U.S. Cl. CPC G03F 7/0002; G03F 7/0017; H10P 76/00

(57) ABSTRACT

Method of manufacturing a nanoimprint lithography replica includes depositing a first resist layer over a substrate and selectively exposing the first resist layer to a first actinic radiation. The selectively exposed first resist layer is developed to form a pattern in the first resist layer. The pattern in the first resist layer is extended into the substrate to form a mold in the substrate. The first resist layer is removed from the substrate. A second resist layer deposited over a replica blank. The second resist layer is contacted with the mold. The second resist layer is exposed to a second actinic radiation. The mold and the exposed second resist layer are separated. A pattern is formed in the exposed second resist layer. The pattern in the second resist layer is extended into the replica blank, and the second resist layer is removed from the replica blank to form a replica.

### RELATED APPLICATION

This application claims priority to U.S. Provisional Ser. No. 63/698,327 filed Sep. 24, 2024, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). While photolithographic techniques, such as EUVL provide high resolution patterns, they are very expensive techniques. It is desirable to reduce the cost of lithography. Nanoimprint lithography is proposed as a lower cost alternative to EUVL. However, nanoimprint lithography may suffer from critical dimension limitations and defect detection issues.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a process stage of a sequential operation according to an embodiment of the disclosure.

FIG. 2 shows a process stage of a sequential operation according to an embodiment of the disclosure.

FIGS. 3A and 3B show process stages of a sequential operation according to embodiments of the disclosure.

FIG. 4 shows a process stage of a sequential operation according to an embodiment of the disclosure.

FIG. 5 shows a process stage of a sequential operation according to an embodiment of the disclosure.

FIG. 6 shows a process stage of a sequential operation according to an embodiment of the disclosure.

FIGS. 7A, 7B, 7C, 7D, 7E, and 7F show process stages of a sequential operation according to an embodiment of the disclosure.

FIGS. 8A, 8B, 8C, 8D, and 8E show process stages of a sequential operation according to an embodiment of the disclosure.

FIGS. 9A, 9B, and 9C show process stages of mold patterning according to an embodiment of the disclosure. FIGS. 9D, 9E, 9F, 9G, and 9H show process stages of mold patterning according to an embodiment of the disclosure.

FIGS. 10A, 10B, 10C, and 10D show process stages of mold patterning according to an embodiment of the disclosure.

FIGS. 11A, 11B, and 11C show process stages of transfer and correction of optical exposure overlay distortions in the molds according to an embodiment of the disclosure.

FIGS. 12A and 12B show process stages of improving critical dimension uniformity of mold patterns according to an embodiment of the disclosure.

FIG. 13 shows a cross sectional view of a nanoimprint lithography mask according to embodiments of the present disclosure.

FIGS. 14A and 14B show a plan view and cross-sectional view, respectively, of semiconductor device manufacturing operation using a nanoimprint lithography mask according to embodiments of the present disclosure.

FIGS. 15A and 15B show a plan view and cross-sectional view, respectively, of semiconductor device manufacturing operation using a nanoimprint lithography mask according to embodiments of the present disclosure.

FIGS. 16A, 16B, 16C, 16D, 16E, 16F, and 16G schematically illustrate sequential operations of manufacturing a semiconductor device according to embodiments of the disclosure.

FIGS. 17A, 17B, 17C, 17D, 17E, 17F, 17G, and 17H schematically illustrate sequential operations of manufacturing a semiconductor device according to embodiments of the disclosure.

FIGS. 18A and 18B show a controller that controls various operations of manufacturing a semiconductor device according to embodiments of the disclosure.

FIG. 19 shows a flowchart of a method of manufacturing a nanoimprint lithography replica in accordance with embodiments of the present disclosure.

FIG. 20 shows a flowchart of a method of manufacturing a nanoimprint lithography replica in accordance with embodiments of the present disclosure.

FIG. 21 shows a flowchart of a method of manufacturing a semiconductor device in accordance with embodiments of the present disclosure.

FIG. 22 shows a flowchart of a method of manufacturing a nanoimprint lithography replica in accordance with embodiments of the present disclosure.

FIG. 23 shows a flowchart of a method of manufacturing a semiconductor device in accordance with embodiments of the present disclosure.

FIG. 24 shows a flowchart of a method of manufacturing a semiconductor device in accordance with embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Furthermore, the term “based” means that the composition, compound, or alloy contains 50 wt. % or more by weight of the material on which it is based.

Nanoimprint lithography (NIL) has been proposed as a lower cost alternative to extreme ultraviolet (EUV) lithography to form nanometer scale device features. Nanoimprint lithography replicas are also referred to as masks and stamps, and such terms are used interchangeably in the present disclosure. Embodiments of the present disclosure provide methods of manufacturing a nanoimprint lithography replica (or mask) and methods of manufacturing a semiconductor device. More specifically, the present disclosure provides techniques to reduce the cost of manufacturing nanoimprint lithography replicas with improved critical dimension uniformity (CDU) and reduced defects. The production of lower cost, higher resolution replicas with fewer defects also reduces the cost of and improves the efficiency of the semiconductor device manufacturing operations.

Embodiments of the disclosure are directed to a new mold mask process for nanoimprint lithography. An optical projection patterning process is used in the imprint mold mask writing process to overcome critical dimension (CD) limitations, improve critical dimension uniformity (CDU) performance, enable defect inspection, and reduce the cost. By using an optical projection patterning process, the mold mask for imprinting gains a n:1 shrinkage benefit on CD resolution, CDU reduction, allowance of die-to-die defect inspection, and cost reduction.

Embodiments of the disclosure employ an nX optical master mask in the patterning of the mold, where n is a factor of image size reduction in transferring the image from the mask to the replica mold features formed in the mold by the photolithographic process of forming a mold pattern in the mold substrate. In some embodiments, n of nX is 2, 3, 4, 5, 6, 7, 8, 9, or 10, but it is not limited thereto. In some embodiments, n is greater than 10.

Substrates patterned by the imprinting process demonstrate superior performance in terms of resolution and critical dimension uniformity.

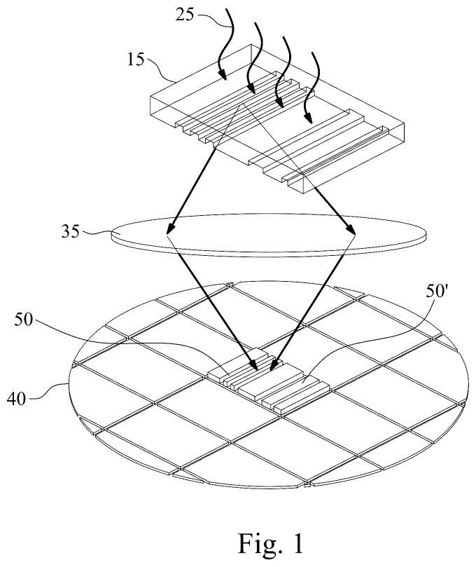

FIG. 1 is a schematic illustration of the method of forming a mold for forming NIL replicas. As shown in FIG. 1, actinic radiation 25 is directed to a photomask 15. The photomask 15 patterns the actinic radiation to provide a latent pattern of the features to be formed in the mold substrate 40. The patterned radiation is modified by optics 35 in the photolithography system to reduce the image scale of the pattern to be formed on the substrate 40, thereby forming mold features 50′ (e.g.-lines, trenches, etc.) having smaller dimensions than the corresponding features on the photomask 15. One or more molds 50 are formed on the substrate 40 in some embodiments.

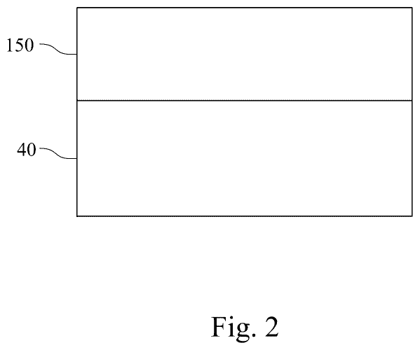

FIGS. 2-6 illustrate a method of manufacturing a mold for forming replicas according to embodiments of the disclosure. A resist, such as a photoresist, is coated on a surface of a layer to be patterned or a substrate 40, in some embodiments, to form a resist layer 150, such as a photoresist layer 150, as shown in FIG. 2. Then the photoresist layer 15 undergoes a first baking operation to evaporate solvents in the photoresist composition in some embodiments. The photoresist layer 150 is baked at a temperature and time sufficient to cure and dry the photoresist layer 150 in some embodiments. In some embodiments, the photoresist layer 150 is heated to a temperature of about 40° C. to about 120° C. for about 10 seconds to about 10 minutes.

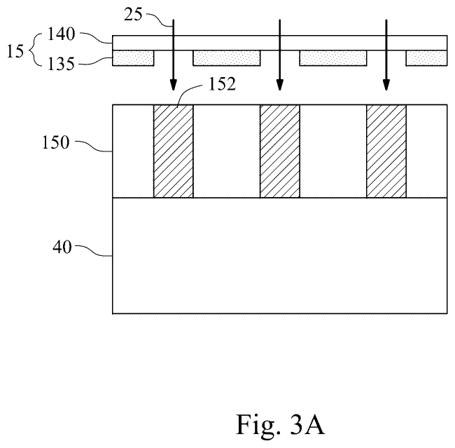

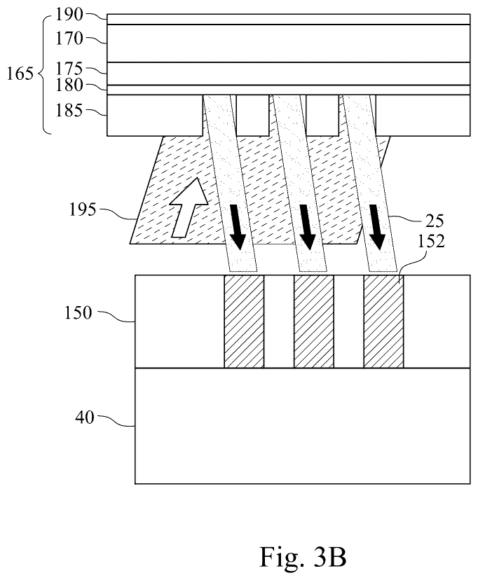

After the first baking operation, the photoresist layer 150 is selectively exposed to actinic radiation 25 (see FIGS. 3A and 3B) in operation. In some embodiments, the photoresist layer 150 is selectively exposed to ultraviolet radiation. In some embodiments, the ultraviolet radiation is deep ultraviolet radiation (DUV). In some embodiments, the ultraviolet radiation is extreme ultraviolet (EUV) radiation. In some embodiments, the radiation is an electron beam.

As shown in FIG. 3A, the exposure radiation 25 passes through a photomask 15 before irradiating the photoresist layer 150 in some embodiments. In some embodiments, the photomask has a pattern to be replicated in the photoresist layer 150. The pattern is formed by an opaque pattern 135 on the photomask substrate 140, in some embodiments. The opaque pattern 135 may be formed by a material opaque to ultraviolet radiation, such as chromium, while the photomask substrate 140 is formed of a material that is transparent to ultraviolet radiation, such as fused quartz.

In some embodiments, the selective exposure of the photoresist layer 150 to form exposed regions 152 and unexposed regions 150 is performed using extreme ultraviolet lithography. In an extreme ultraviolet lithography operation, a reflective photomask 165 is used to form the patterned exposure light, as shown in FIG. 3B according to some embodiments. The reflective photomask 165 includes a low thermal expansion glass substrate 170, on which a reflective multilayer 175 of alternating layers of Si and Mo is formed. A capping layer 180 and absorber layer 185 are formed on the reflective multilayer 175. A rear conductive layer 190 is formed on the back side of the low thermal expansion substrate 170. In extreme ultraviolet lithography, extreme ultraviolet radiation 195 is directed towards the reflective photomask 165 at an incident angle of about 6°. A portion 25 of the extreme ultraviolet radiation is reflected by the Si/Mo multilayer 175 towards the photoresist-coated substrate 40, while the portion of the extreme ultraviolet radiation incident upon the absorber layer 185 is absorbed by the photomask. In some embodiments, additional optics 35, including mirrors, are between the reflective photomask 165 and the photoresist-coated substrate. In some embodiments, the additional optics 35 reduce the size of the image from the dimensions of the features on the photomask to the dimensions of the features to be formed on the substrate 40.

The region 152 of the photoresist layer exposed to radiation undergoes a chemical reaction thereby changing its solubility in a subsequently applied developer relative to the region of the photoresist layer not exposed to radiation 150. In some embodiments, the portion 152 of the photoresist layer exposed to radiation undergoes a crosslinking reaction.

Next, the photoresist layer 150 undergoes a post-exposure bake. In some embodiments, the photoresist layer 150 is heated to a temperature of about 70° C. to about 160° C. for about 20 seconds to about 10 minutes. In some embodiments, the photoresist layer 150 is heated for about 30 seconds to about 5 minutes. In some embodiments, the photoresist layer 150 is heated for about 1 minute to about 2 minutes. The post-exposure baking may be used to assist in the generating, dispersing, and reacting of the acid/base/free radical generated from the impingement of the radiation 25 upon the photoresist layer 150 during the exposure. Such assistance helps to create or enhance chemical reactions, which generate chemical differences between the exposed region 152 and the unexposed region 150 within the photoresist layer. These chemical differences also cause differences in the solubility between the exposed region 152 and the unexposed region 150.

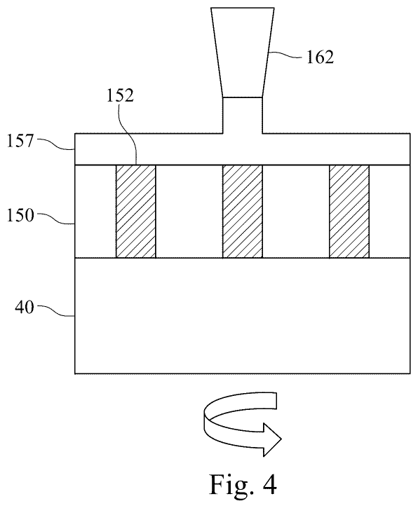

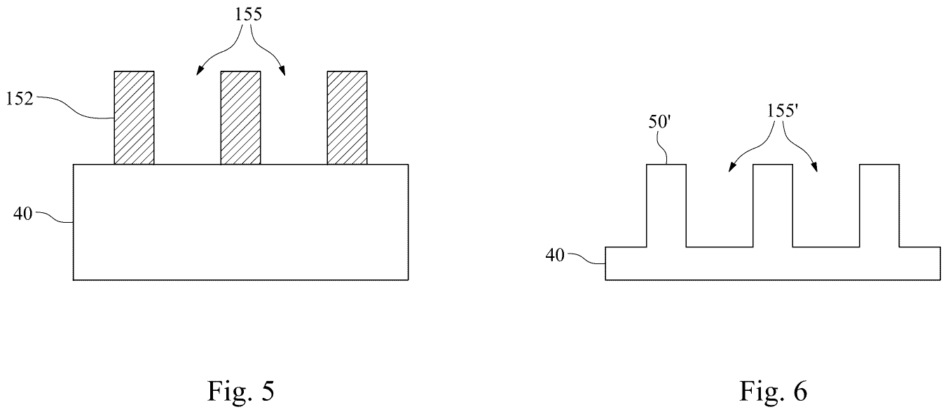

The selectively exposed photoresist layer is subsequently developed by applying a developer to the selectively exposed photoresist layer. As shown in FIG. 4, a developer 157 is supplied from a dispenser 162 to the photoresist layer 150. In some embodiments where the photoresist is a negative-tone photoresist, the unexposed portion of the photoresist layer 150 is removed by the developer 157 forming a pattern of openings 155 in the photoresist layer 150 to expose the substrate 40, as shown in FIG. 5. In other embodiments, where the photoresist is a positive-tone photoresist, the exposed portion of the photoresist layer is removed by the developer 157.

In some embodiments, the pattern of openings 155 in the photoresist layer 150 are extended into the layer to be patterned or substrate 40 to create a pattern of openings 155′ in the substrate 40, thereby transferring the pattern in the photoresist layer 150 into the substrate 40 and forming mold features 50′, as shown in FIG. 6. The pattern is extended into the substrate by etching, using one or more suitable etchants. The exposed portion of the photoresist layer 150 is at least partially removed during the etching operation in some embodiments. In other embodiments, the exposed portion of the photoresist layer 150 is removed after etching the substrate 40 by using a suitable photoresist stripper solvent or by a photoresist ashing operation.

In some embodiments, the substrate 40 is made of silicon, glass, quartz, metal, metal oxide, organic compounds, or combinations thereof. But the substrate is not limited to these materials. In some embodiments, the substrate 40 is a wafer made of one or more of silicon, glass, quartz, metal, metal oxide, and organic compounds, including polymers. In some embodiments, the wafer includes a target layer made of any of silicon, glass, quartz, metal, metal oxide, and organic compounds, including polymers, disposed over the wafer. In some embodiments, the substrate 40 is not a transparent material. When the substrate material is not transparent it is easier to detect defects in the mold in some embodiments.

The photoresist layer 150 is a photosensitive layer that is patterned by exposure to actinic radiation. Typically, the chemical properties of the photoresist regions struck by incident radiation change in a manner that depends on the type of photoresist used. Photoresist layers 150 are either positive-tone resists or negative-tone resists. In some embodiments, the photoresist is a positive-tone resist. A positive-tone resist refers to a photoresist material that when exposed to radiation, such as UV light, becomes soluble in a developer, while the region of the photoresist that is non-exposed (or exposed less) is insoluble in the developer. In other embodiments, the photoresist is a negative-tone resist. A negative-tone resist refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive-tone or negative-tone may depend on the type of developer used to develop the resist. For example, some positive-tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent, such as n-butyl acetate (nBA). Further, whether a resist is a positive or negative-tone may depend on the polymer. For example, in some resists developed with the TMAH solution, the unexposed regions of the photoresist are removed by the TMAH, and the exposed regions of the photoresist, that undergo cross-linking upon exposure to actinic radiation, remain on the substrate after development.

In some embodiments, the photoresist composition includes a polymer, a photoactive compound (PAC), and a solvent. In some embodiments, the photoresist is a chemically amplified resist (CAR) and the photoactive compound is a photoacid generator (PAG). Upon exposure to actinic radiation and the subsequent post-exposure bake, the PAG is activated and generates a photoacid. The photoacid reacts with pendant groups on the polymer, such as crosslinker groups, causing the polymer to crosslink, or acid labile groups, causing the acid labile groups to cleave, and changing the solubility of the exposed regions to a developer.

Photoresist compositions according to the present disclosure include a polymer along with one or more photoactive compounds (PACs) in a solvent, in some embodiments. In some embodiments, the hydrocarbon structure includes a repeating unit that forms a skeletal backbone of the polymer. This repeating unit may include acrylic esters, methacrylic esters, crotonic esters, vinyl esters, maleic diesters, fumaric diesters, itaconic diesters, (meth)acrylonitrile, (meth)acrylamides, styrenes, hydroxystyrenes, vinyl ethers, novolacs, combinations of these, or the like. In some embodiments, the resist includes metal-based composites and metal oxide-based composites.

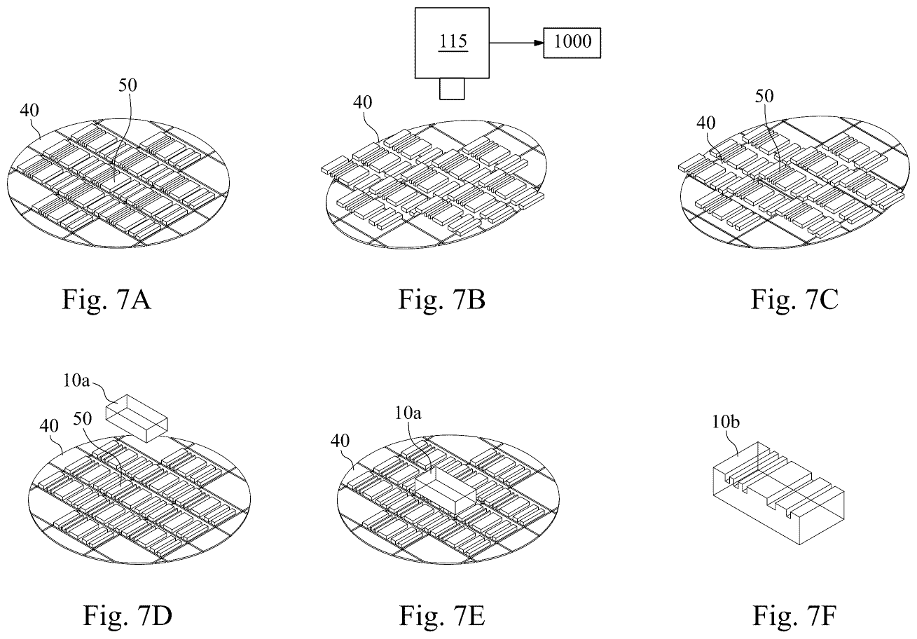

FIGS. 7A-7F illustrate a method of manufacturing a replica mold and replica according to embodiments of the disclosure. One or more replica molds 50 are formed on a substrate 40 according to the operations disclosed herein in reference to FIGS. 1-6, to provide one or more molds 50, as shown in FIG. 7A. The one or more molds 50 are subsequently inspected for defects and the dimensions of the mold features 50′are measured, as shown in FIG. 7B. An inspection system 115 in communication with a controller 1000 is used in some embodiments to inspect the molds and measure the mold features. In some embodiments, the inspection system 115 includes a camera. Using information obtained by the inspection system 115, the controller determines whether dimensions of the patterned mold are within design parameters or design tolerances and whether there are defects in the mold features. The controller 1000 compares images of the mold features and the measured feature dimensions with design data and tolerances stored in the memory of the controller. In some embodiments, the substrate 40 is not transparent, which facilitates the detection of defects. In some embodiments, defects that can be detected by the inspection system include breaks in lines, improper spacing of lines, bridging between adjacent lines, and debris in trenches between lines.

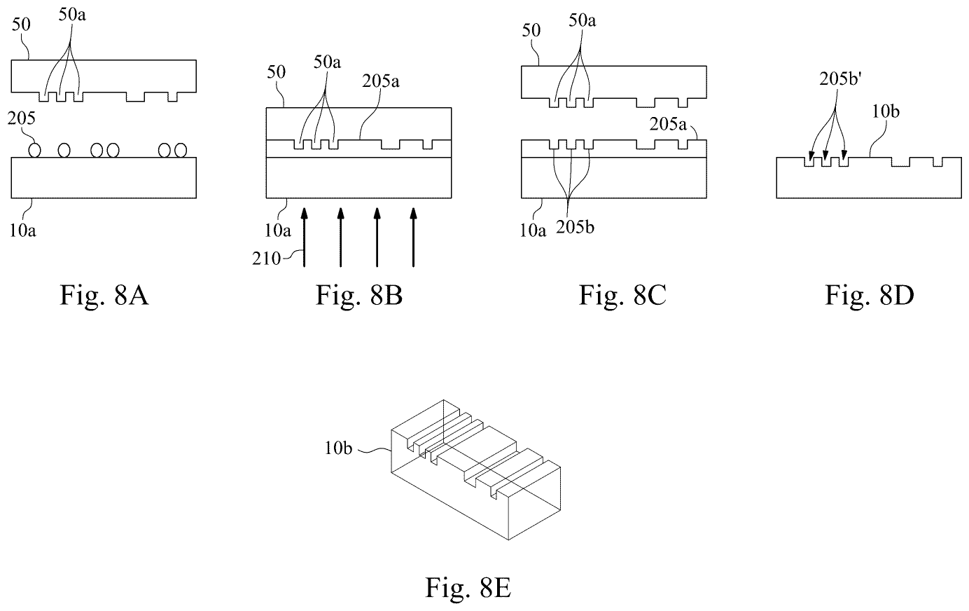

As shown in FIG. 7C, one or more molds 50 having defect levels and feature dimensions within tolerance thresholds are selected as molds for forming replicas. In some embodiments, the mold with the least defects and/or the best CDU is chosen as the mold for forming the replicas. Then, the selected mold 50 is used to manufacture one or more replicas. As shown in FIG. 7D, a replica blank 10a made of a transparent material, such as fused silica, is aligned with the replica mold 50. The replica mold is used to transfer the mold pattern into the replica blank through a resist layer on the replica blank, as shown in FIG. 7E. The resulting replica 10b that can be used to manufacture semiconductor devices is illustrated in FIG. 7F. The replica manufacturing operations will be explained in greater detail in FIGS. 8A-8E.

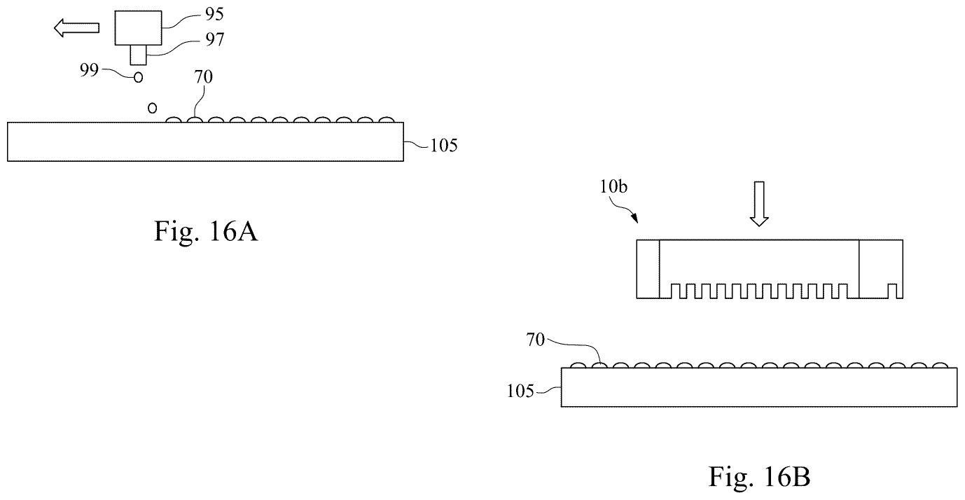

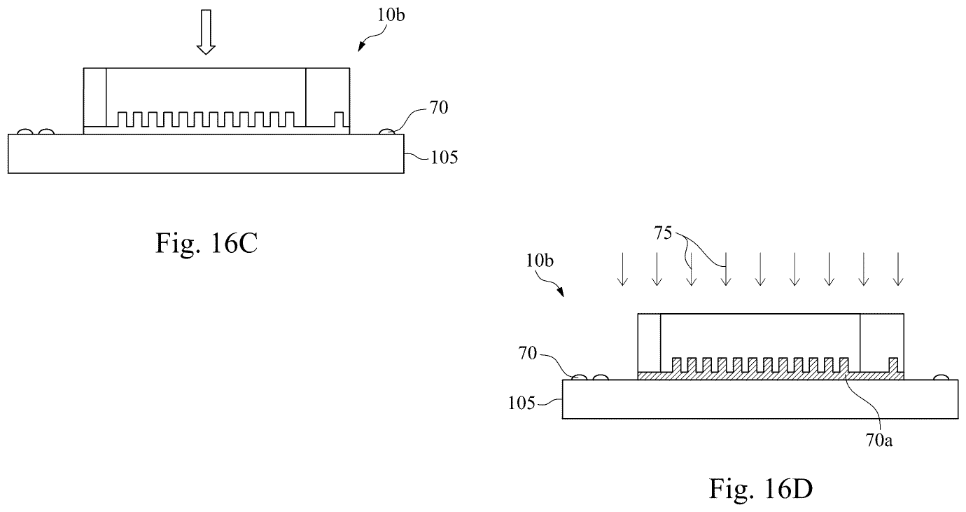

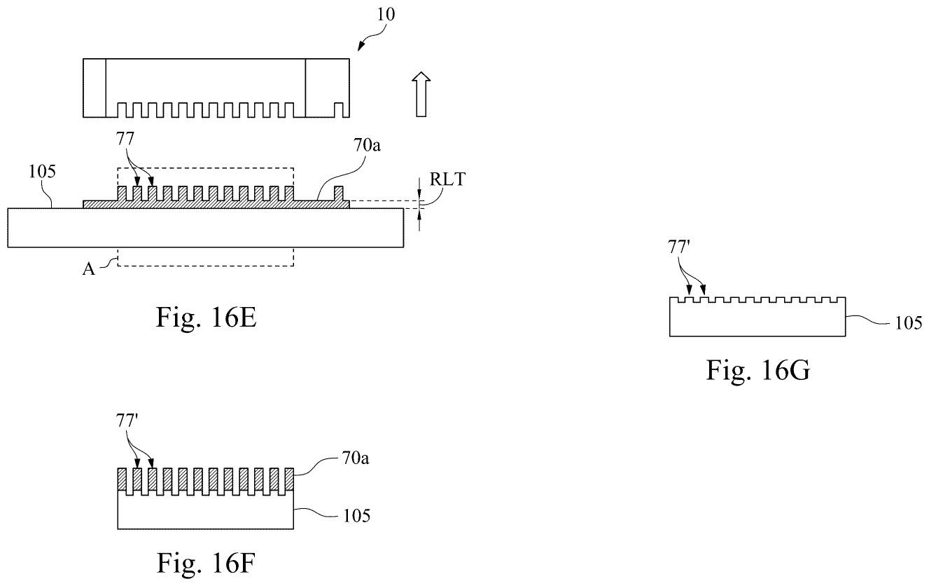

A resist layer 205 is disposed over the replica blank 10a, as shown in FIG. 8A. The resist layer may be formed of any of the resist materials disclosed herein. In some embodiments, the resist layer 205 is a photoresist that is applied to the replica blank 10a is applied as droplets ejected from an inkjet printer. The inkjet deposition operation will be described in greater detail in reference to FIGS. 16A-16C infra. The mold 50 is brought into contact with the resist layer 205. The mold 50 is pressed into the resist layer 205. The pressure causes the resist droplets on the surface of the replica blank 10a to spread and merge. The recesses in the mold 50 are filled with the resist material by capillary action. The surface of the replica or mask 10b does not contact the replica mold 50 during the patterning operations in some embodiments because directly contacting the replica blank 10a to the mold 50 may damage the replica or mold.

As shown in FIG. 8B, ultraviolet radiation 210 from an ultraviolet radiation source passes through the ultraviolet transparent replica blank 10a exposing the resist layer 205 to form a cured resist layer 205a, thereby transferring the pattern 50a in the mold to the resist layer 205a.

In some embodiments, the ultraviolet radiation source (not shown) includes a mercury vapor lamp; halogen lamps; gas discharge lamps, including argon and deuterium arc lamps, mercury-xenon arc lamps, and metal-halide arc lamps; ultraviolet light emitting diodes; and excimer lasers, including KrF and ArF lasers.

The mold 50 is separated from the cured, patterned resist layer 205a, as shown in FIG. 8C. The recesses in the pattern 205b in the cured photoresist layer 205a corresponds to the projections in the pattern 50a in the mold 50. Then, using the patterned resist layer 205a as a mask, the patterned resist layer 205a and the replica blank 10a are etched to extend the pattern in the resist layer 205b into the replica blank 10a to form a replica 10b including a pattern 205b′ corresponding to the pattern 205b in the resist layer, as shown in FIG. 8D. Remaining portions of the resist layer 205a are removed by a suitable resist stripping operation, including a plasma ashing operation or a solvent stripping operation. An isometric view of the replica 10b produced by the disclosed embodiments is shown in FIG. 8E.

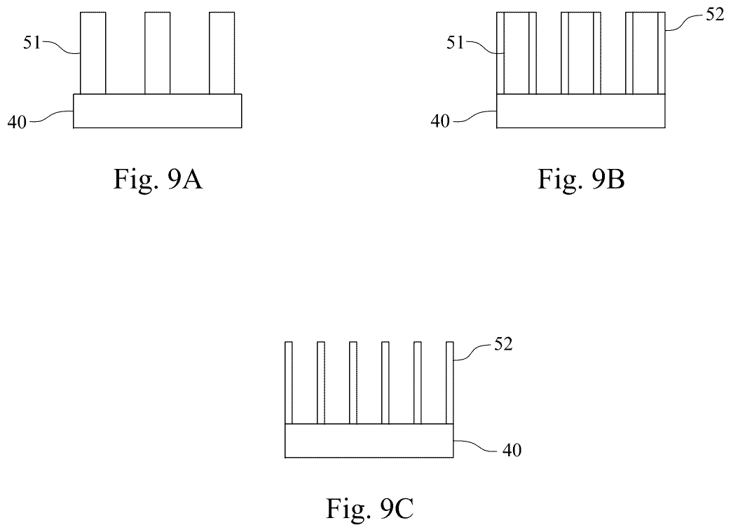

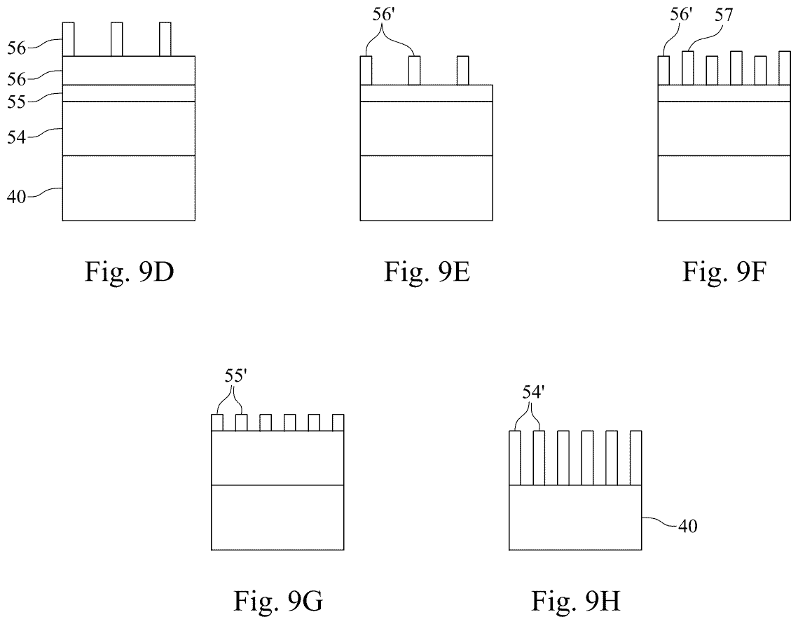

The molds 50 may be patterned by any suitable method. For example, the mold features may be patterned using one or more photolithography processes, including double-patterning or multi-patterning processes to increase the pattern feature density. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate 40 and patterned using a photolithography process to form sacrificial features 51, as shown in FIG. 9A. Spacers 52 are formed alongside the patterned sacrificial layer using a self-aligned process, as shown in FIG. 9B. The sacrificial layer 51 is then removed leaving the remaining spacers 52 as the mold pattern features, as shown in FIG. 9C.

In another embodiment, multi-patterning is used to create mold features having critical dimensions smaller than would be otherwise obtainable by a single, direct photolithography process, as shown in FIGS. 9D-9H. A target layer 54 to be formed into mold pattern features is deposited over the substrate 40, as shown in FIG. 9D. Then a first hard mask layer 55 and a second hard mask layer 56 is formed over the target layer 54. The first hard mask layer 55 and the second hard mask layer 56 are formed of different materials having different etch selectivities. For example, one hard mask layer may be a nitride layer and the other hard mask layer may be an oxide layer. A photoresist layer 56 is then formed over the second hard mask layer and patterned. The patterned photoresist layer 56 is used as a mask while the second hard mask layer is etched to form a patterned second hard mask layer 56′, as shown in FIG. 9E. Then a second photoresist layer 57 is formed over the patterned second hard mask layer 56′and the first hard mask layer 55 and patterned, as shown in FIG. 9F. The second photoresist pattern 57 is formed between the patterned second hard mask features 56′. In some embodiments, this is done by using the same photomask used in patterning the first photoresist layer 56 and laterally shifting the photomask before exposing the second photoresist layer 57. Using the patterned second hard mask layer 56′and the second patterned photoresist layer 57 as masks, the first hard mask layer 55 is patterned to form a patterned first hard mask layer 55′, as shown in FIG. 9G. In this embodiment, the patterned hard mask layer 55′has twice the line pattern density than the patterned second hard mask layer 56′. Then, the patterned first hard mask layer 55′is used as a mask for etching the target layer 54 to form mold features 54′, as shown in FIG. 9H.

The high patterning resolution and fidelity achieved by the multiple-patterning methods described in FIGS. 9A-9C and 9D-9H can be implemented on the mold and duplicated onto the replicas or masks 10b according to the methods described in FIGS. 8A-8E.

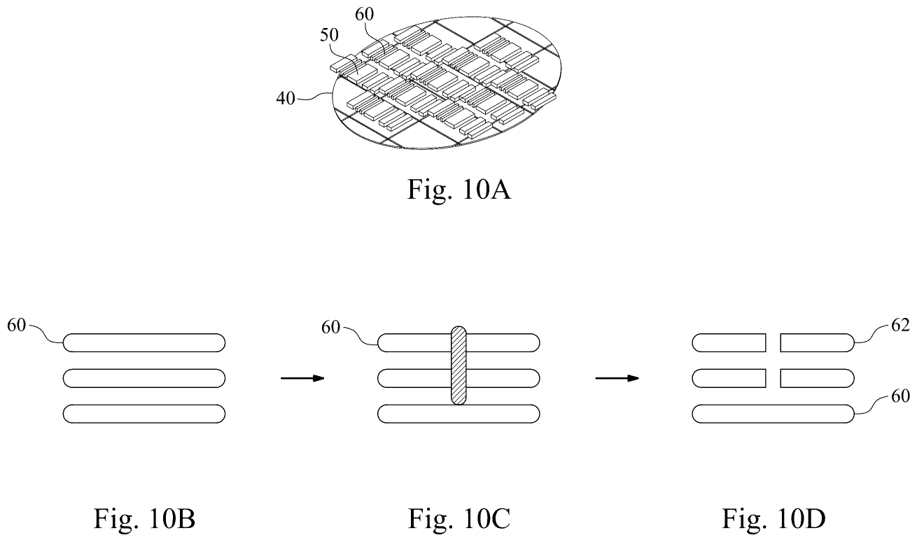

In other embodiments, the mold features are further reduced in size by use of mandrel patterning and cutting operations, as shown in FIGS. 10A-10D. One or molds 50 having a plurality of mold features or mandrels 60 are formed according to any of the methods described herein by FIGS. 1-6 and 9A-9H, as shown in FIG. 10A. In some embodiments, the mold pattern is made up of a plurality of parallel mandrels 60, as shown in FIG. 10B. One or more of the plurality of mandrels 60 are cut using photolithographic operations, as shown in FIG. 10C, to produce cut mold features 62 having smaller CD, as shown in FIG. 10D. The molds 50 formed in the methods described in FIGS. 10A-10D are subsequently used to form replicas 10b according to the methods described in FIGS. 8A-8E.

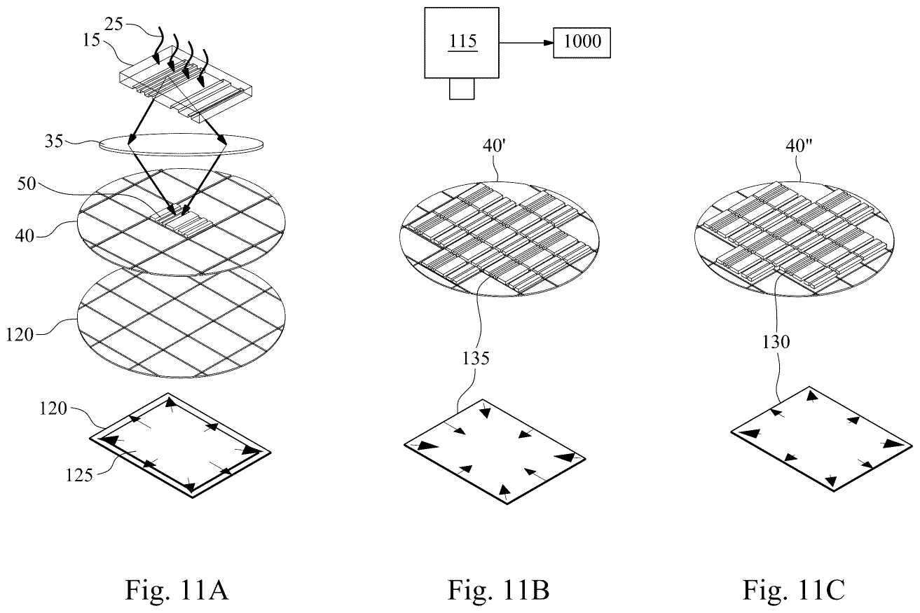

In other embodiments, patterning overlay correction techniques are used to transfer and correct optical exposure overlay distortions on the replica and reducing overlay residue to adjacent layers. As shown in FIG. 11A, a mold 50 is formed on a substrate by the lithography operations disclosed herein. In some embodiments, there is an overlay deformation, as illustrated by the non-corrected overlay and the target overlay 125. The arrows illustrate the amount and direction of the overlay deformation. Using the inspection system 115 and controller 1000, an overlay compensation amount 135 to correct the overlay deformation is determined, as shown in FIG. 11B. The overlay compensation is applied in FIG. 11C and another mold is formed with a reduced amount of overlay deformation 130, as illustrated by the shorter arrows.

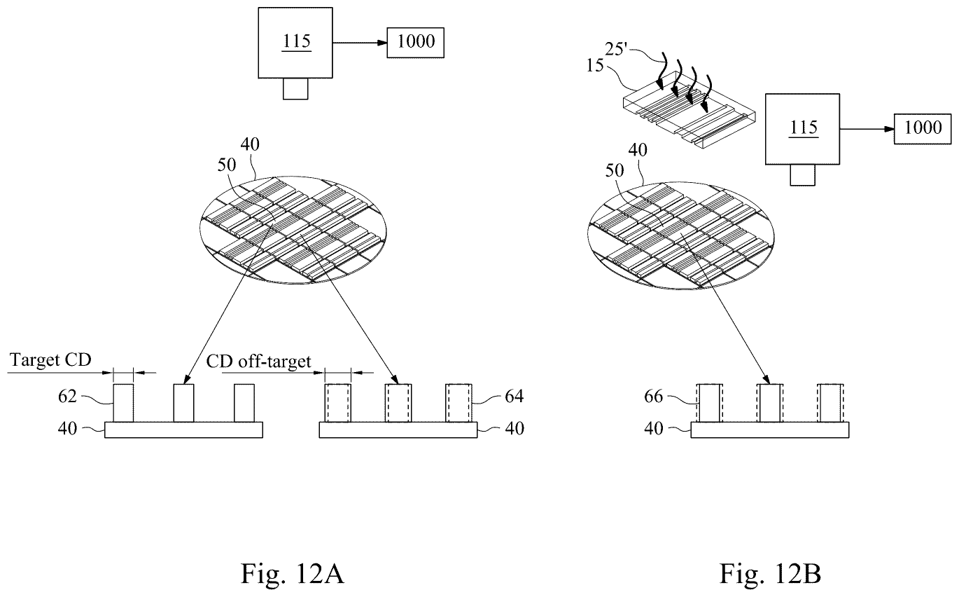

Embodiments of the disclosure improve CD uniformity. As shown in FIG. 12A, after a mold 40 is formed, the critical dimension (CD) of the mold pattern features 64 are measured and compared to the target CD of the mold patterns 62, using the inspection system 115 and controller 1000. When the critical dimension is not within design tolerances, one or more parameters of the photolithographic operations are adjusted, and another mold is formed using the adjusted photolithographic parameters. Adjustable parameters of the photolithographic operations include, but are not limited to, the exposure dose, exposure time, post exposure baking parameters, and development temperature. For example, in some embodiments the exposure dose of the actinic radiation 25 is adjusted and another replica mold 50 is formed at the adjusted exposure dose of actinic radiation 25′. The critical dimension of the mold features 66 of the another mold are measured using the inspection system 115 and controller 1000, as shown in FIG. 12B, and if the critical dimension is within design tolerance the replica mold is used to form replicas. In the embodiment of FIGS. 12A and 12B, for example, if the inspection determines that the critical dimension is off target because the exposure dose is too low, the next mold would be formed using a higher exposure dose.

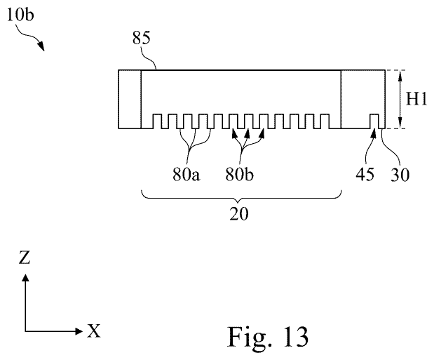

FIG. 13 shows a plan view of a nanoimprint lithography replica 10b according to embodiments of the present disclosure. In some embodiments, the replica 10b includes a pattern region (or device region) 20 including a pattern corresponding to features formed on a device. In some embodiments, the pattern corresponds to features of a semiconductor device. In some embodiments, the patterns correspond to an integrated circuit. The patterned region is surrounded by a frame region 30. In some embodiments, the frame region 30 is rectangular shape, and has a width W1 ranging from about 13 mm to about 152 mm, and a height H1 ranging from about 15 mm to about 152 mm. In some embodiments, the frame width W1 ranges from about 20 mm to about 76 mm, and the frame height H1 ranges from about 25 mm to about 96 mm. In some embodiments, the frame width W1 is about 26 mm and the height H1 is about 33 mm.

In some embodiments, the frame region 30 includes portions where an alignment mark pattern 45 is formed. In some embodiments, the alignment mark pattern 45 is a trench. The alignment mark pattern is used for aligning the replica on the substrate to be patterned.

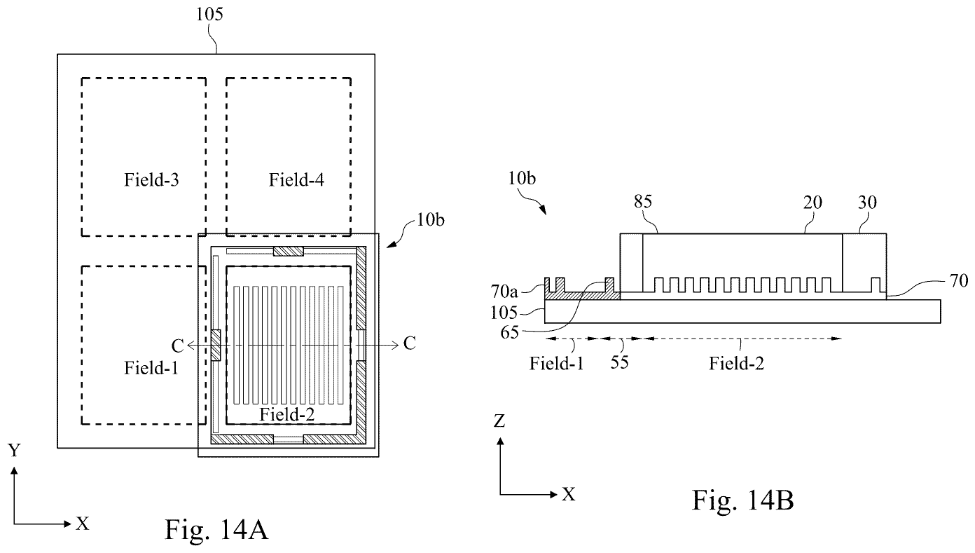

FIGS. 14A and 14B show a plan view and cross-sectional view, respectively, of a semiconductor device manufacturing operation using a nanoimprint lithography replica according to embodiments of the present disclosure. FIG. 14A shows the mask 10b positioned over a pattern field of the substrate 105. FIG. 14B shows a cross-sectional view seen along line C-C of FIG. 14A.

The substrate 105 is a semiconductor substrate, such as a wafer, or other suitable substrate to be patterned to form an integrated circuit thereon is provided. In some embodiments, the semiconductor substrate includes silicon. Alternatively or additionally, the semiconductor substrate includes germanium, silicon germanium, or other suitable Group IV or Group III-V semiconductor materials. The substrate 105 includes a single crystalline semiconductor layer on at least its surface portion, according to some embodiments. The substrate 105 may include a single crystalline semiconductor material such as, but not limited to Si, Ge, SiGe, GaAs, InSb, GaP, GaSb, InAlAs, InGaAs, GaSbP, GaAsSb, and InP. In some embodiments, the substrate 105 is a silicon layer of an SOI (silicon-on insulator) substrate. In certain embodiments, the substrate 105 is made of crystalline Si.

The substrate 105 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 105. The germanium concentration of the SiGe buffer layers may increase from 30 atomic % for the bottom-most buffer layer to 70 atomic % for the top-most buffer layer.

In some embodiments, the substrate 105 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 105 includes titanium, aluminum, cobalt, ruthenium, titanium nitride, tungsten nitride, tantalum nitride, and combinations thereof.

In some embodiments, the substrate 105 includes a dielectric material having at least a silicon or metal oxide or nitride of the formula MX_{b}, where M is a metal or Si, X is N or O, and b ranges from about 0.4 to about 2.5. In some embodiments, the substrate 105 includes silicon dioxide, silicon nitride, aluminum oxide, hafnium oxide, lanthanum oxide, and combinations thereof.

In the embodiment shown in FIGS. 14A and 14B, the replica 10b is shown overlying pattern field 2 of the semiconductor substrate, after the replica 10b was used to form the cured, patterned resist layer 70a in pattern field 1. As shown in FIG. 14B, the resist layer 70a in pattern field 1 is cured because it has already been exposed to ultraviolet radiation, while the resist layer 70 in pattern field 2 is not cured because it has not been exposed to ultraviolet radiation.

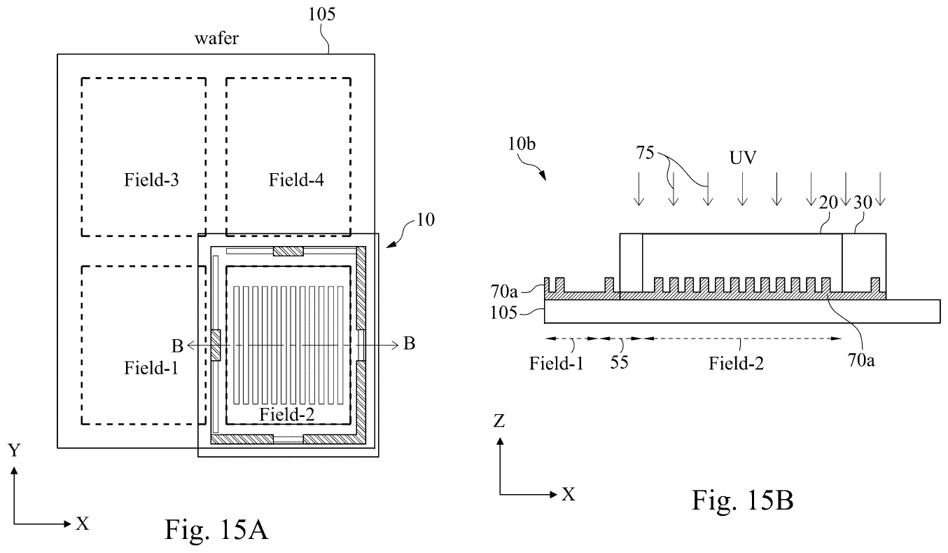

FIGS. 15A and 15B show a plan view and cross-sectional view, respectively, of a semiconductor device manufacturing operation using a nanoimprint lithography replica according to embodiments of the present disclosure. FIG. 15B is a cross-section seen along line B-B of FIG. 15A. As shown in FIG. 15B, ultraviolet radiation 75 from an ultraviolet radiation source passes through the ultraviolet transmissive portions of the replica 10b exposing the resist layer to form the cured resist layer 70a, thereby transferring the pattern in the pattern region 20 of the replica 10b to the resist layer 70a.

In some embodiments, the ultraviolet radiation source (not shown) includes a mercury vapor lamp; halogen lamps; gas discharge lamps, including argon and deuterium arc lamps, mercury-xenon arc lamps, and metal-halide arc lamps; ultraviolet light emitting diodes; and excimer lasers, including KrF and ArF lasers.

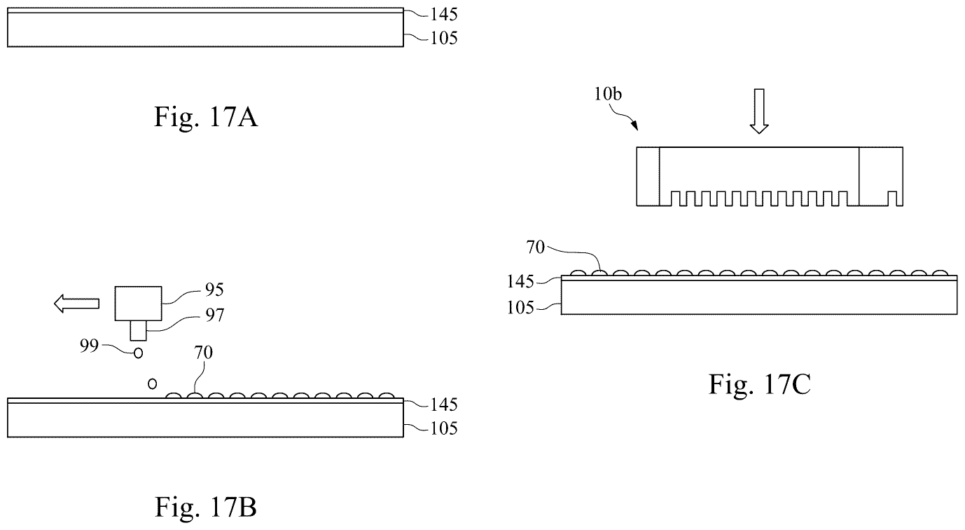

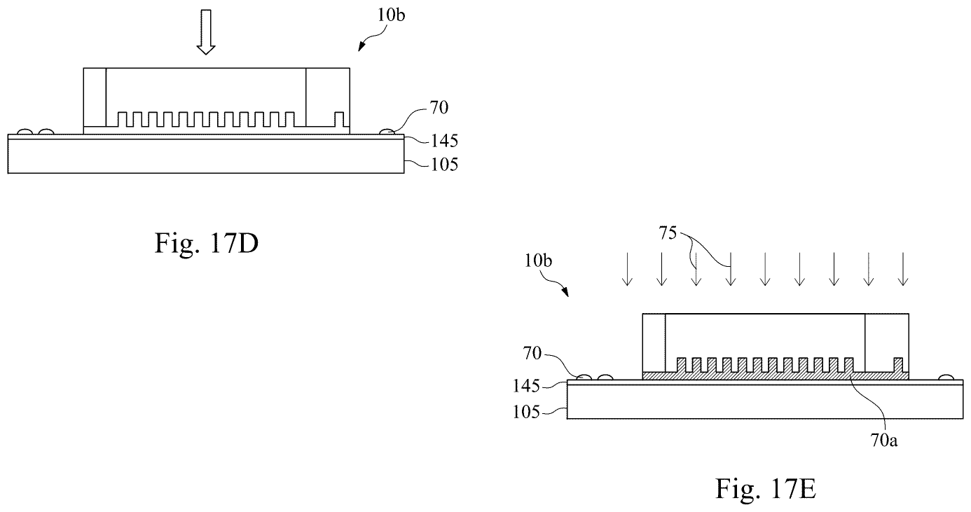

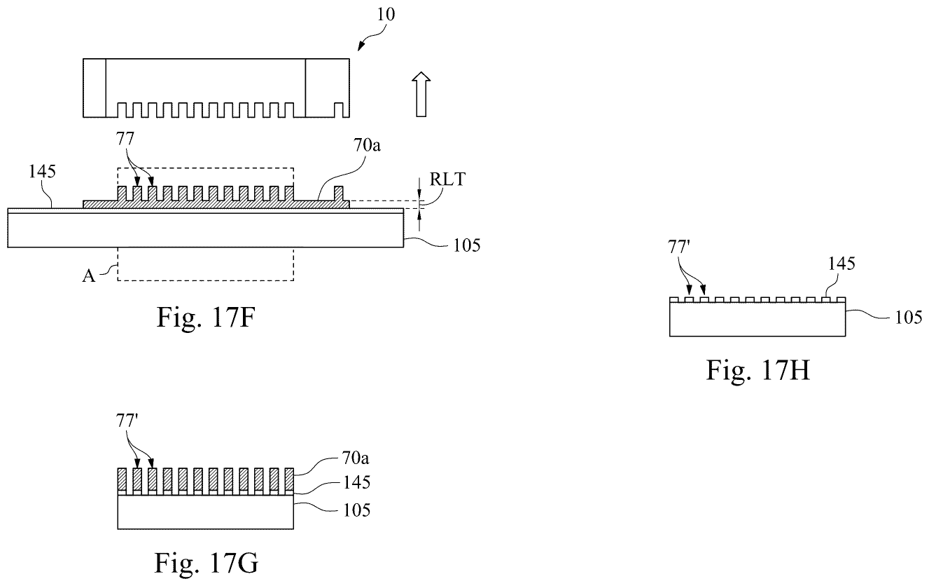

The nanoimprint lithography methods according to embodiments of the disclosure will be discussed in further detail in reference to FIGS. 16A-17H. FIGS. 16A-16G schematically illustrate sequential operations of manufacturing a semiconductor device according to embodiments of the disclosure.

A resist material is deposited over a substrate 105 to form a resist layer 70. In some embodiments, the resist layer is deposited using an inkjet printer 95, as shown in FIG. 16A. The inkjet 95 dispenses droplets 99 of resist material from an inkjet head. The inkjet head may include a plurality of nozzles 97 that simultaneously dispenses a plurality of resist material droplets. In some embodiments, the inkjet head may include hundreds of nozzles 97. In some embodiments, the inkjet printer 95 moves laterally relative to the substrate 105 while depositing resist material droplets 99 over the surface of the substrate 105. In some embodiments, the inkjet 95 and the substrate are appropriately sized so that an entire pattern field is deposited simultaneously. In some embodiments, the resist droplet volumes range from about 0.1 pL to about 100 μL, in other embodiments the droplet volume ranges from about 1 pL to about 10 μL, and other embodiments, the droplet volume ranges from about 1 nL to about 1 μL. The resist layer 70 can be formed by other suitable techniques in other embodiments, such as by a spin coating operation.

The resist material includes polymerizable monomers or oligomers in some embodiments that polymerize when exposed to ultraviolet radiation. In some embodiments, the resist material includes a photoactive component, including one or more of a photosensitizer, photoinitiator, and photoacid generator. In some embodiments, polymerizable monomer includes acrylates, methacrylates, epoxies, vinyl ethers, and thiols and alkenes.

The resist material composition includes a solvent in some embodiments. The solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK). In some embodiments, the resist-coated substrate is heated after depositing the resist layer to drive off the solvent.

A shown in FIG. 16B, a replica 10b according to embodiments of the present disclosure is positioned over the resist-coated substrate 105. Then, as shown in FIG. 16C, the replica 10b is pressed into the resist layer 70. The pressure causes the resist droplets on the surface of the substrate 105 to spread and merge. The recesses in the replica 10b are filled with the resist material by capillary action. A portion of the resist material spreads up the sidewall of the replica outside the frame region by capillary action in some embodiments.

Next, as shown in FIG. 16D, the resist layer 70 is exposed to ultraviolet radiation 75 through the replica 10b, and the exposed resist layer is cured or hardened. During the ultraviolet radiation exposure, the resist material in the exposed portions of the resist layer 70a polymerize and/or crosslink.

The replica 10b is subsequently removed from the resist-coated substrate leaving the patterned resist layer 70a including pattern 77 on the substrate 105, as shown in FIG. 16E. In some embodiments, the surface of the pattern in the pattern region 20 of the replica is coated with an anti-stick agent to prevent the resist layer from sticking to the replica. The surface of the replica or mask 10b does not contact the substrate 105 during the patterning operations in some embodiments. Therefore, portions of the resist layer between the replica 10b and the substrate 105 are also cured during the ultraviolet radiation exposure operation resulting in a residual layer thickness (RLT) of the cured resist layer 70a over the substrate 105. The thickness of the RLT can be adjusted by controlling various resist and pattern forming parameters including resist material, resist viscosity, type of solvent in the resist material, solvent concentration in the resist material, and stamping pressure. In some embodiments, the RLT has a thickness of about 0.1 nm to about 10 nm. In some embodiments, the RLT has a thickness of about 1 nm. While it may be desirable to minimize the thickness of the RLT, completely eliminating the RLT may not be desirable, because directly contacting the replica 10b to the substrate 105 may damage the replica or substrate.

In some embodiments, the RLT is subsequently removed by a suitable dry etching technique, such as plasma etching or reactive ion etching, as shown in FIG. 16F. Through etching, the resist pattern 77 is extended through the RLT and into the substrate 105 forming a pattern 77′in the substrate. In some embodiments, the etch chemistry and etching parameters are adjusted during the etching operation depending on the material being etched (i.e.—cured resist material or substrate). In some embodiments, the resist pattern is then subsequently removed from the patterned substrate 105 using a suitable resist stripping or plasma ashing operation, as shown in FIG. 16G.

FIGS. 17A-17G schematically illustrate sequential operations of manufacturing a semiconductor device according to embodiments of the disclosure. The process of FIGS. 17A-17G is similar to that disclosed in reference to FIGS. 16A-16G, with the addition of a target layer 145 to be patterned disposed over the substrate 105, as shown in FIG. 17A. In some embodiments, the target layer 145 includes a conductive layer, such as a metallic layer or a polysilicon layer, a dielectric layer, such as silicon oxide, silicon nitride, SiON, SiOC, SiOCN, SiCN, hafnium oxide, or aluminum oxide, or a semiconductor layer, such as an epitaxially formed semiconductor layer. In some embodiments, the target layer 145 is formed over an underlying structure, such as isolation structures, transistors, or wirings.

A resist material is deposited over the target layer 145 to form a resist layer 70. In some embodiments, the resist layer is deposited using an inkjet printer 95, as shown in FIG. 17B, and disclosed herein in reference to FIG. 16A. The resist layer 70 can be formed by other suitable techniques in other embodiments, such as by a spin coating operation.

A shown in FIG. 17C, a replica 10b according to embodiments of the present disclosure is positioned over the resist-coated target layer 145. Then, as shown in FIG. 17D, the replica is pressed into the resist layer 70. The pressure causes the resist droplets on the surface of the target layer 145 to spread and merge. The recesses in the replica 10b are filled with the resist material by capillary action. A portion of the resist material spreads up the sidewall of the replica outside the frame region by capillary action in some embodiments.

Next, as shown in FIG. 17E, the resist layer 70 is exposed to ultraviolet radiation 75 through the replica 10b, and the exposed resist layer is cured or hardened. During the ultraviolet radiation exposure, the resist material in the exposed portions of the resist layer 70a polymerize and/or crosslink.

The replica 10b is subsequently removed from the resist-coated target layer 145 leaving the patterned resist layer 70a including pattern 77 on the substrate 105, as shown in FIG. 17F. In some embodiments, the surface of the pattern in the pattern region 20 of the replica is coated with an anti-stick agent to prevent the resist layer from sticking to the mask. The surface of the replica or mask 10b does not contact the target layer 145 during the patterning operations in some embodiments, resulting in a residual layer thickness (RLT) of the cured resist layer 70a over the target layer 145. The thickness of the RLT can be adjusted by controlling various resist and pattern forming parameters including resist material, resist viscosity, type of solvent in the resist material, solvent concentration in the resist material, and stamping pressure. While it may be desirable to minimize the thickness of the RLT, completely eliminating the RLT may not be desirable, because directly contacting the replica 10b to the target layer 145 may damage the replica or substrate.

In some embodiments, the RLT is subsequently removed by a suitable dry etching technique, such as plasma etching or reactive ion etching, as shown in FIG. 17G. The resist pattern 77 is extended through the RLT and into the target layer 145 forming a pattern 77′ in the target layer. In some embodiments, the etch chemistry and etching parameters are adjusted during the etching operation depending on the material being etched (i.e.-cured resist material or target layer).

In some embodiments, the resist pattern is then subsequently removed from the patterned target layer using a suitable resist stripping or plasma ashing operation, as shown in FIG. 17H.

After the replica or mask 10b is removed from the resist material, any uncured resist material is removed from the surface of the target layer and/or replica by use of a suitable air flushing technique or by a solvent, in some embodiments.

Additional operations may be performed on the structure of FIGS. 16G and 17H, including forming transistors, including fin field effect transistors (FinFETs), gate-all-around field effect transistors (GAA FETs), bipolar transistors, and planar transistors; memory devices; capacitors; insulating layers; and metal wiring layers, including interconnects and vias. The structures of FIGS. 16G and 17H may be part of a larger integrated circuit, including additional devices and components.

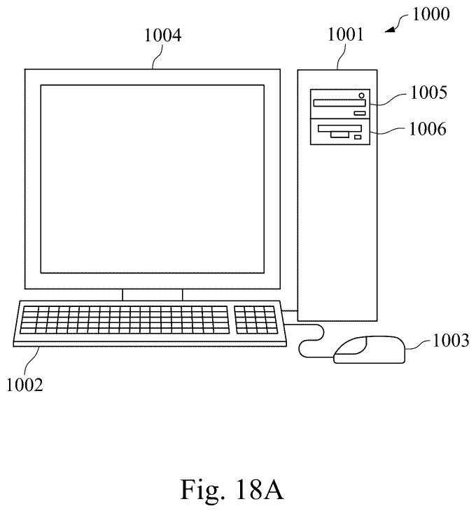

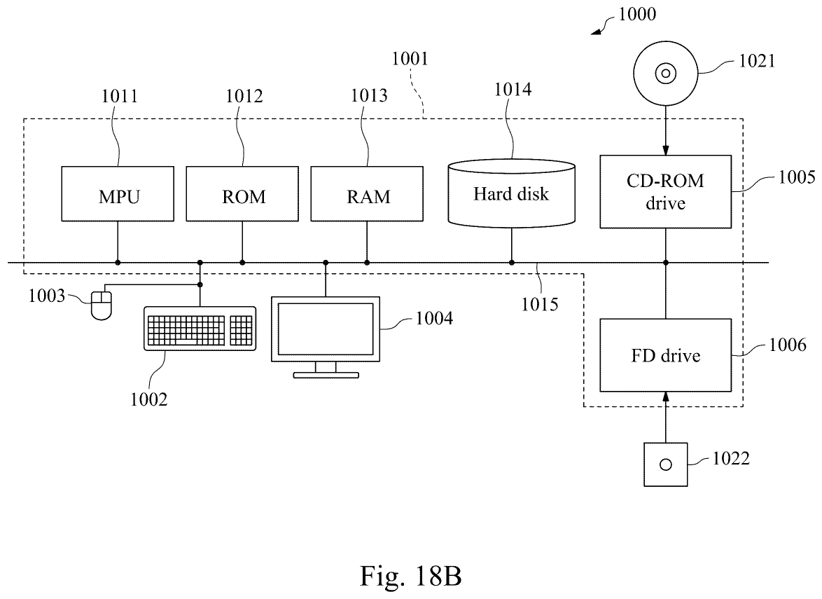

FIG. 18A is a schematic view of a computer system 1000 that functions as a controller of the mold, replica, and semiconductor device inspection and manufacturing operations in embodiments of the disclosure. All of or a part of the processes, methods, and/or operations of the foregoing embodiments can be realized using computer hardware and computer programs executed thereon. In FIG. 18A, a computer system 1000 is provided with a computer 1001 including an optical disk read only memory (e.g., CD-ROM or DVD-ROM) drive 1005 and a magnetic disk drive 1006, a keyboard 1002, a mouse 1003, and a monitor 1004.

FIG. 18B is a diagram showing an internal configuration of the computer system 1000. In FIG. 18B, the computer 1001 is provided with, in addition to the optical disk drive 1005 and the magnetic disk drive 1006, one or more processors, such as a micro processing unit (MPU) 1011, a read only memory (ROM) 1012 in which a program such as a boot up program is stored, a random access memory (RAM) 1013 that is connected to the MPU 1011 and in which a command of an application program is temporarily stored and a temporary storage area is provided, a hard disk 1014 in which an application program, a system program, and data are stored, and a bus 1015 that connects the MPU 1011, the ROM 1012, and the like. Note that the computer 1001 may include a network card (not shown) for providing a connection to a LAN.

The program for causing the computer system 1000 to execute the functions for the lithographic and inspection systems in the foregoing embodiments may be stored in an optical disk 1021 or a magnetic disk 1022, which are inserted into the optical disk drive 1005 or the magnetic disk drive 1006, and transmitted to the hard disk 1014. Alternatively, the program may be transmitted via a network (not shown) to the computer 1001 and stored in the hard disk 1014. At the time of execution, the program is loaded into the RAM 1013. The program may be loaded from the optical disk 1021 or the magnetic disk 1022, or directly from a network. The program does not necessarily have to include, for example, an operating system (OS) or a third-party program to cause the computer 1001 to execute the functions of lithographically patterning and inspecting the mold, replica, and semiconductor device, and the lithography system in the foregoing embodiments. The program may only include a command portion to call an appropriate function (module) in a controlled mode and obtain desired results.

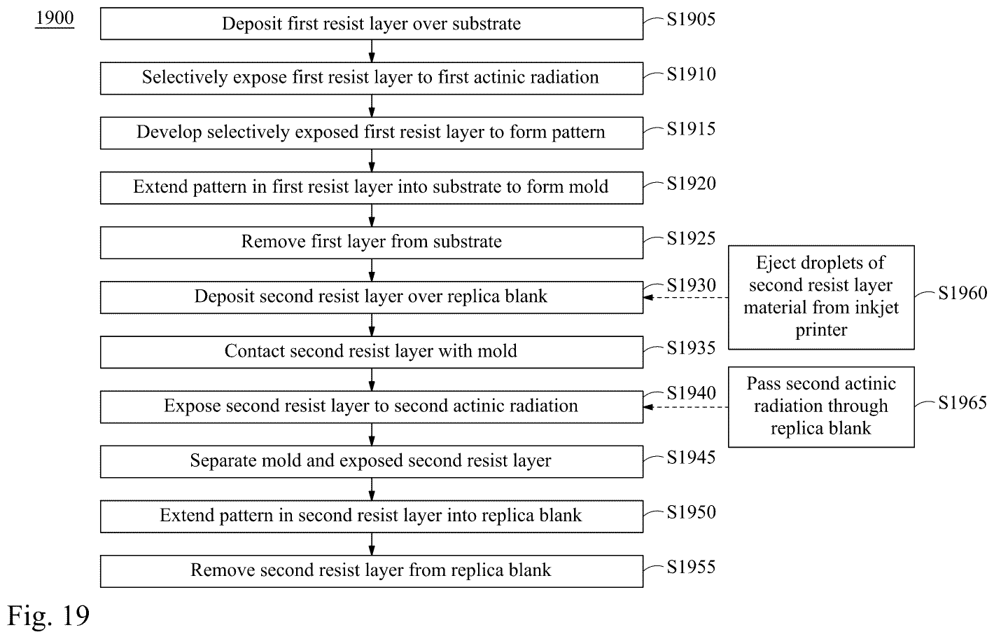

FIG. 19 shows a flowchart of a method 1900 of manufacturing a nanoimprint lithography replica in accordance with embodiments of the present disclosure. The method 1900 includes an operation S1905 of depositing a first resist layer 150 over a substrate 40 and selectively exposing the first resist layer 150 to a first actinic radiation 25 in operation S1910. The selectively exposed first resist layer 150, 152 is developed in operation S1915 to form a pattern 155 in the first resist layer. The pattern 155 in the first resist layer is extended into the substrate 40 to form a mold 50 having a pattern 50a in the substrate in operation S1920. The first resist layer is subsequently removed from the substrate in operation S1925. In operation S1930, a second resist layer 205 is deposited over a replica blank 10a. The second resist layer 205 is contacted with the mold 50 in operation S1935. Then, in operation S1940, the second resist layer 205 is exposed to a second actinic radiation 75. After exposing the second resist layer 205 to the second actinic radiation, the mold 50 and the exposed second resist layer 205a are separated in operation S1945. A pattern 205b is formed in the exposed second resist layer 205a corresponding to the pattern 50a in the mold 50. In operation S1950, the pattern 205b in the second resist layer 205a is extended into the replica blank 10a, and the second resist layer is removed from the replica blank 10a in operation S1955 to form a replica 10b. In some embodiments, the selectively exposing the first resist layer 150 to a first actinic radiation 25 includes directing the actinic radiation 25 towards a photomask 15. In some embodiments, during operation S1930, droplets 99 of a second resist layer material 205 are ejected from an inkjet printer 95 over the replica blank in operation S1960. In some embodiments, during operation 1940, the second actinic radiation 75 passes through the replica blank 10a to expose second resist layer 205 in operation S1965.

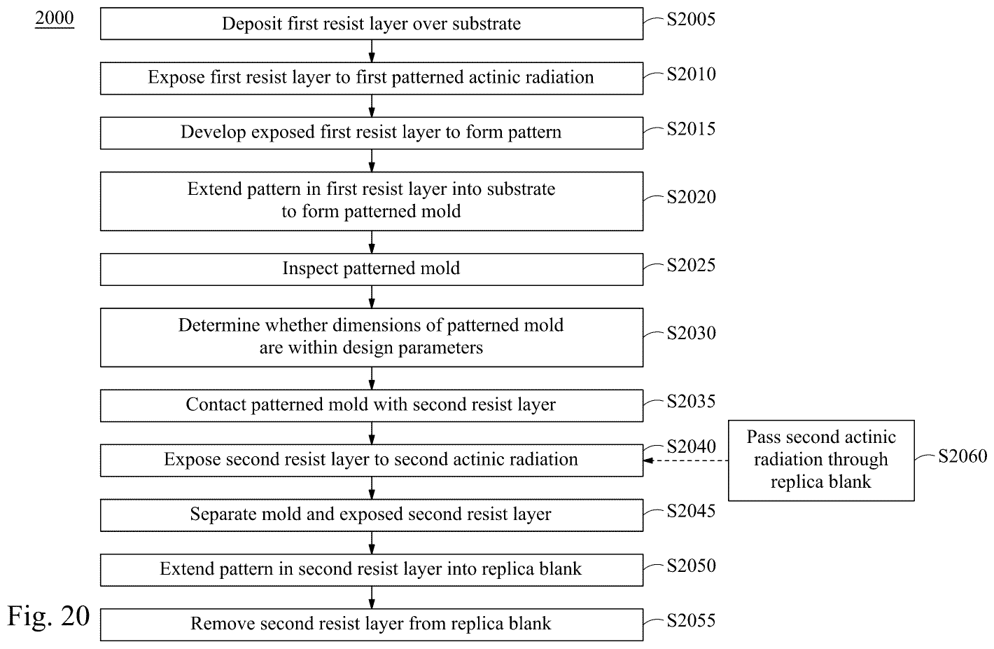

FIG. 20 shows a flowchart of a method 2000 of manufacturing a nanoimprint lithography replica in accordance with embodiments of the present disclosure. The method 2000 includes an operation S2005 of depositing a first resist layer 150 over a substrate 40, and exposing the first resist layer 150 to a first patterned actinic radiation 25 in operation S2010. The first patterned actinic radiation 25 is patterned by a photomask 15. The exposed first resist layer 150, 152 is developed to form a pattern 155 in the first resist layer in operation S2015. Then, in operation S2020, the pattern 155 in the first resist layer is extended into the substrate 40 to form a patterned mold 50 in the substrate 40. The patterned mold is inspected in operation S2025, and whether dimensions of the patterned mold are within design parameters is determined in operation S2030. In operation S2035, the patterned mold 50 is contacted with a second resist layer 205 disposed over a replica blank 10a when the dimensions of the patterned mold are within the design parameters. The second resist layer 205 is exposed to a second actinic radiation 75 in operation S2040. Then, in operation S2045, the mold 50 and the exposed second resist layer 205a are separated. A pattern 205b is formed in the exposed second resist layer. The pattern 205b in the second resist layer is extended into the replica blank 10a in operation S2050, and the second resist layer is removed from the replica blank to form a replica 10b in operation S2060. In some embodiments, during operation S2040, the second actinic radiation 75 passes through the replica blank 10a to expose the second resist layer in operation S2060.

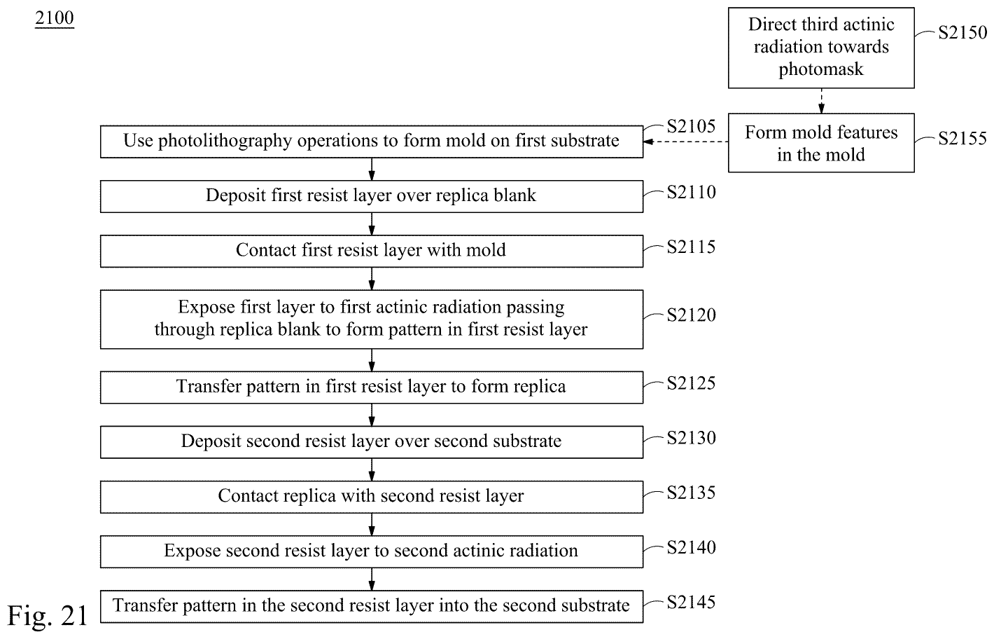

FIG. 21 shows a flowchart of a method 2100 of manufacturing a semiconductor device in accordance with embodiments of the present disclosure. The method 2100 includes an operation S2105 of using photolithography operations to form a mold 50 on a first substrate 40. In operation S2110, a first resist layer 205 is deposited over a replica blank 10a. Then, the first resist layer 205 is contacted with the mold 50 in operation S2115. The first resist layer 205 is exposed to a first actinic radiation 75 passing through the replica blank to form a pattern 205b in the first resist layer in operation S2120. Exposing the first resist layer 205 to the first actinic radiation 75 hardens exposed portions 205a of the first resist layer. In operation S2125, the pattern 205b in the first resist layer is transferred into the replica blank 10a to form a replica 10b. In operation S2130, a second resist layer 70 is deposited over a second substrate 105. The replica 10b is contacted with the second resist layer 70 in operation S2135. Then, in operation S2140, the second resist layer 70 is exposed to a second actinic radiation 75 passing through the replica to form a pattern 77 in the second resist layer in operation S2140. The exposing the second resist layer 70 to actinic radiation 75 hardens exposed portions of the second resist layer. The pattern 77 in the second resist layer is transferred into the second substrate 105 in operation S2145. In some embodiments, during operation S2105, a third actinic radiation 25 is directed towards a photomask 115 including one or more pattern features in operation S2150, and one or more mold features 50′are formed in the mold 50 corresponding to the one or more pattern features in the photomask in operation S2155, wherein dimensions of the one or mold features are smaller than the corresponding one or more pattern features in the photomask.

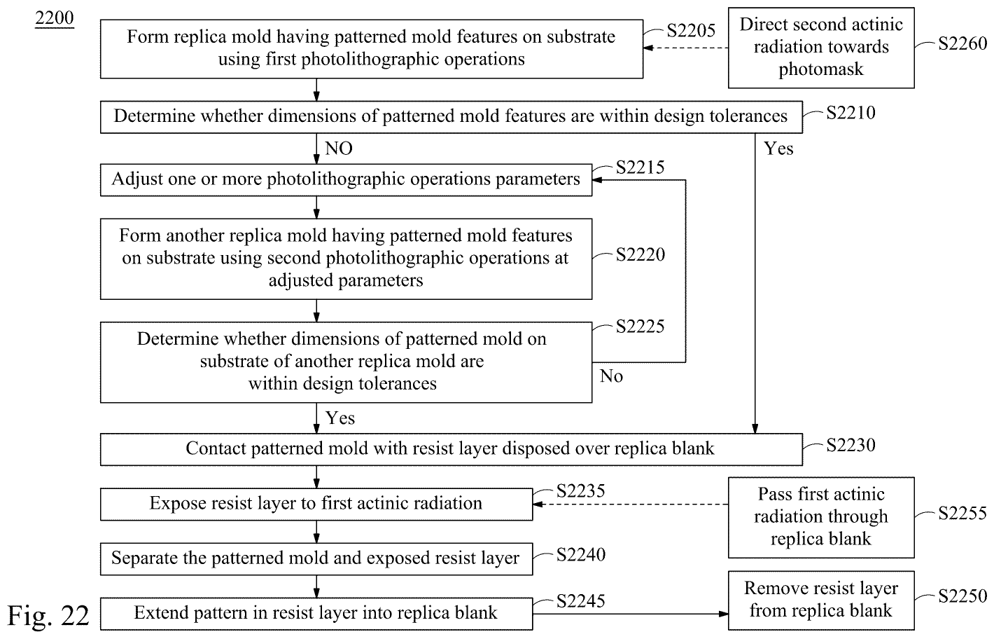

FIG. 22 shows a flowchart of a method 2200 of manufacturing a nanoimprint lithography replica in accordance with embodiments of the present disclosure. The method 2200 includes an operation S2205 of forming a replica mold 50 having patterned mold features 50′ on a substrate 40 using first photolithographic operations. In operation S2210, whether dimensions of the patterned mold features are within design tolerances is determined. When the dimensions of the patterned mold features are not within the design tolerances: one or more parameters of the photolithographic operations are adjusted in operation S2215, another replica mold having patterned mold features on the substrate is formed using second photolithographic operations at the adjusted parameters in operation S2220, and whether dimensions of the patterned mold on the substrate of the another replica mold are within the design tolerances is determined in operation S2225. When the dimensions of the patterned mold features are within the design tolerances: the patterned mold 50 is contacted with a resist layer 205 disposed over a replica blank 10a in operation 2230, the resist layer 205 is exposed to a first actinic radiation 210 in operation S2235, the patterned mold 50 and the exposed resist layer 205a are separated in operation S2240, a pattern 205b is formed in the exposed resist layer, the pattern in the resist layer 205b is extended into the replica blank 10a in operation S2245, and the resist layer is removed from the replica blank 10a in operation S2250 to form a replica 10b. In some embodiments, during operation S2235, the actinic radiation 210 passes through the replica blank 10a to expose the resist layer 205 in operation S2255. In an embodiment, during operation S2205, a second actinic radiation 25 is directed towards a photomask 15 including photomask pattern features corresponding to the mold features 50 in operation S2260, and dimensions of the mold features are smaller than the corresponding photomask pattern features.

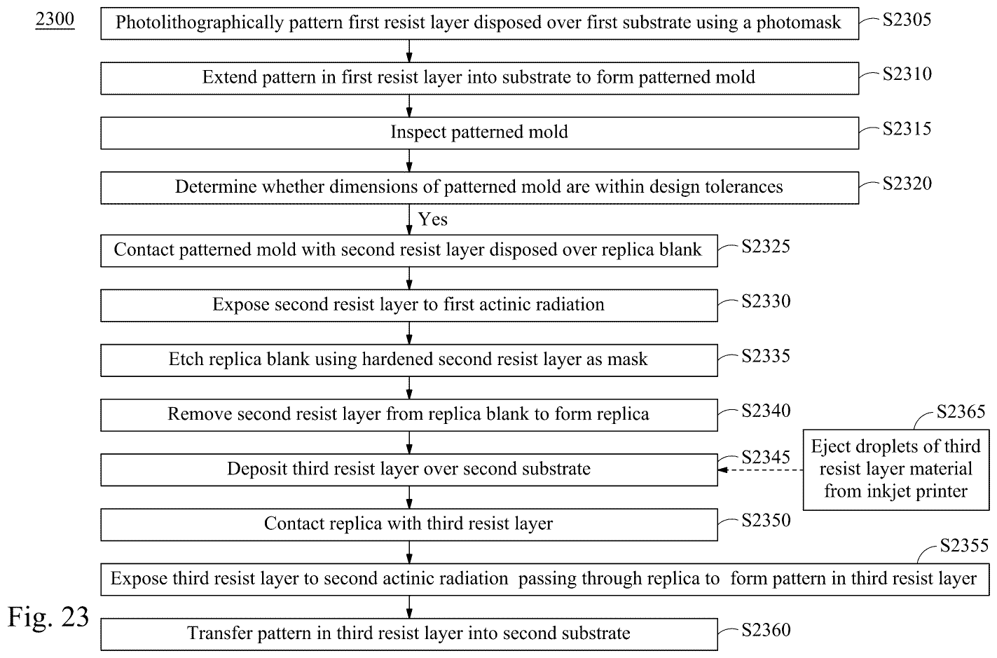

FIG. 23 shows a flowchart of a method 2300 of manufacturing a semiconductor device in accordance with embodiments of the present disclosure. The method 2300 includes an operation S2305 of photolithographically patterning a first resist layer 155 disposed over a first substrate 40. The photolithographically patterning is performed using a photomask 15. A pattern 155 formed in the first resist layer is extended into the substrate 40 to form a patterned mold 50 in the substrate in operation S2310. In operation S2315, the patterned mold 50 is inspected, and whether dimensions of the patterned mold are within design tolerances is determined in operation S2320. In operation S2325, the patterned mold 50 is contacted with a second resist layer 205 disposed over a replica blank 10a when the dimensions of the patterned mold are within the design tolerances. The second resist layer 205 is exposed to a first actinic radiation 210 in operation S2330, wherein portions of the second resist layer are hardened by exposure to the first actinic radiation. In operation S2325, the replica blank 10a is etched using the hardened second resist layer 205b as a mask. The second resist layer is removed from the replica blank 10a to form a replica 10b in operation S2340. Then, in operation S2345, a third resist layer 70 is deposited over a second substrate 105. The replica 10b is contacted with the third resist layer 70 in operation S2350. In operation S2355, the third resist layer 70 is exposed to a second actinic radiation 75 passing through the replica 10a to form a pattern 77 in the third resist layer 70. The exposing the third resist layer 70 to actinic radiation 75 hardens exposed portions of the third resist layer. In operation S2360, the pattern 77 in the third resist layer is transferred into the second substrate 105. In an embodiment, operation S2345 includes an operation S2365 of ejecting droplets 99 of a third resist layer material from an inkjet printer 95 over the substrate 105.

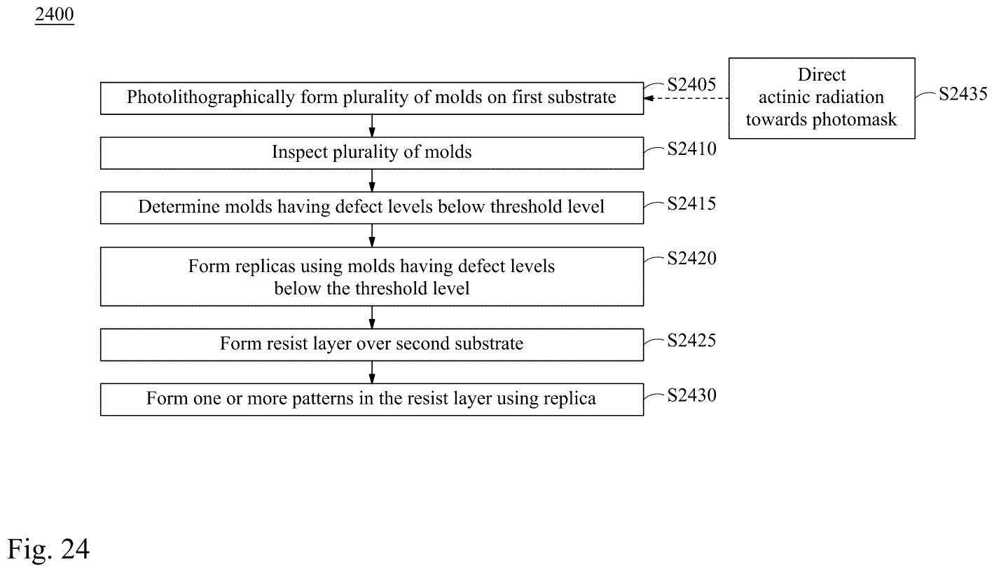

FIG. 24 shows a flowchart of a method 2400 of manufacturing a semiconductor device in accordance with embodiments of the present disclosure. The method 2400 includes an operation S2405 of using photolithography operations to form a plurality of molds 50 on a first substrate 40. The plurality of molds 50 are inspected for defects in operation S2410, and which of the plurality of molds have defect levels below a threshold level is determined in operation S2415. In operation S2420, one or more replicas 10b are formed using one or more of the plurality of molds 50 having defect levels below the threshold level. In operation S2425, a resist layer 70 is formed over a second substrate 105, and the one or more replicas 10b are used to form one or more patterns 77 in the resist layer 70 in operation S2430. In an embodiment, during operation S2405: actinic radiation 25 is directed towards a photomask 15 including one or more photomask pattern features in operation S2435, and one or more mold features 50′are formed in each of the plurality of molds 50 corresponding to the one or more pattern features, wherein dimensions of the one or mold features are smaller than the corresponding one or more pattern features.

Embodiments of the present disclosure include methods of manufacturing replica molds, replicas, and semiconductor devices having improved critical dimension uniformity (CDU). An optical projection patterning process is used in the replica mold manufacturing process that overcomes critical dimension (CD) limitations, enables improved defect inspection, and reduces the cost and time for manufacturing a replica mold over e-beam replica mold manufacturing processes. In embodiments of the disclosure, finer replica mold features and increased replica mold pattern density are achieved by optical reduction of the photomask pattern used in imaging the replica mold pattern. In some embodiments, the dimensions of the photomask pattern dimensions are reduced by a factor of 10 or more. In some embodiments, improved CDU and reduced overlay difference between the replica mold and the optical exposure system is achieved by inspecting the replica mold, determining whether the replica mold features and overlay deformation are within design tolerances, adjusting the mold manufacturing parameters, and forming additional molds using the adjusted manufacturing parameters.

Additional benefits of embodiments of the disclosure include the ability to quickly manufacture multiple replica molds, the multiple replica molds can be inspected, and the replica molds having the lowest defect levels can be selected for manufacturing replicas. In addition, photolithographic process parameters can be adjusted to tune the CD. Further, higher throughput are achievable because embodiments of the disclosure can reduce the mold mask fabrication cycle time to less than about 2 days at reduced cost and with better CD uniformity and ability to provide a flexible target CD range.

In some embodiments, embodiments of the disclosure provide replica molds and replicas having a CD resolution of less than about 26 nm and a CDU in a range of about 0.5 nm to about 6 nm.

It will be understood that not all advantages have been necessarily discussed herein, no particular advantage is required for all embodiments or examples, and other embodiments or examples may offer different advantages.

A method of manufacturing a nanoimprint lithography replica according to an embodiment of the disclosure includes depositing a first resist layer over a substrate and selectively exposing the first resist layer to a first actinic radiation. The selectively exposed first resist layer is developed to form a pattern in the first resist layer. The pattern in the first resist layer is extended into the substrate to form a mold in the substrate. The first resist layer is removed from the substrate. A second resist layer deposited over a replica blank. The second resist layer is contacted with the mold. The second resist layer is exposed to a second actinic radiation. The mold and the exposed second resist layer are separated. A pattern is formed in the exposed second resist layer. The pattern in the second resist layer is extended into the replica blank, and the second resist layer is removed from the replica blank to form a replica. In an embodiment, the selectively exposing the first resist layer to a first actinic radiation includes directing the first actinic radiation towards a photomask. In an embodiment, the first actinic radiation is deep ultraviolet or extreme ultraviolet radiation. In an embodiment, the exposing the second resist layer to the second actinic radiation hardens exposed portions of the second resist layer. In an embodiment, the second actinic radiation is ultraviolet radiation. In an embodiment, the depositing the second resist layer over a replica blank comprises ejecting droplets of a second resist layer material from an inkjet printer over the replica blank. In an embodiment, during the exposing the second resist layer to the second actinic radiation, the second actinic radiation passes through the replica blank to expose second resist layer. In an embodiment, the substrate is made of one or more materials selected from the group consisting of silicon, a silicon oxide, a silicon nitride, carbon, SiOC, SiON, SiOCN, a metal, a metal oxide, and an ultraviolet radiation organic compound. In an embodiment, the substrate includes a silicon wafer. In an embodiment, the replica blank is made of fused silica.

Another embodiment of the disclosure is a method of manufacturing a nanoimprint lithography replica includes depositing a first resist layer over a substrate, and exposing the first resist layer to a first patterned actinic radiation. The first patterned actinic radiation is patterned by a photomask. The exposed first resist layer is developed to form a pattern in the first resist layer. The pattern in the first resist layer is extended into the substrate to form a patterned mold in the substrate. The patterned mold is inspected and whether dimensions of the patterned mold are within design parameters is determined. The patterned mold is contacted with a second resist layer disposed over a replica blank when the dimensions of the patterned mold are within the design parameters. The second resist layer is exposed to a second actinic radiation. The mold and the exposed second resist layer are separated. A pattern is formed in the exposed second resist layer. The pattern in the second resist layer is extended into the replica blank, and the second resist layer is removed from the replica blank to form a replica. In an embodiment, the substrate includes a target layer disposed over a wafer. In an embodiment, the wafer is a silicon wafer, and the target layer includes one or more materials selected from the group consisting of a silicon oxide, a silicon nitride, carbon, SiOC, SiON, SiOCN, a metal, a metal oxide, and ultraviolet radiation absorbing organic compounds. In an embodiment, the replica blank is made of fused silica. In an embodiment, during the exposing the second resist layer to the second actinic radiation, the second actinic radiation passes through the replica blank to expose the second resist layer.

Another embodiment of the disclosure is a method of manufacturing a semiconductor device, including using photolithography operations to form a mold on a first substrate. A first resist layer is deposited over a replica blank. The first resist layer is contacted with the mold. The first resist layer is exposed to a first actinic radiation passing through the replica blank to form a pattern in the first resist layer. Exposing the first resist layer to the first actinic radiation hardens exposed portions of the first resist layer. The pattern in the first resist layer is transferred into the replica blank to form a replica. A second resist layer is deposited over a second substrate. The replica is contacted with the second resist layer. The second resist layer is exposed to a second actinic radiation passing through the replica to form a pattern in the second resist layer. The exposing the second resist layer to actinic radiation hardens exposed portions of the second resist layer. The pattern in the second resist layer is transferred into the second substrate. In an embodiment, during the photolithography operation: a third actinic radiation is directed towards a photomask including one or more pattern features, and one or more mold features are formed in the mold corresponding to the one or more pattern features, wherein dimensions of the one or mold features are smaller than the corresponding one or more pattern features. In an embodiment, dimensions of the one or more mold features are 2 to 10 times smaller than the corresponding one or more pattern features. In an embodiment, the third actinic radiation is deep ultraviolet radiation or extreme ultraviolet radiation. In an embodiment, the first and second substrates include silicon wafers.

Another embodiment of the disclosure includes a method of manufacturing a nanoimprint lithography replica, including forming a replica mold having patterned mold features on a substrate using first photolithographic operations. Whether dimensions of the patterned mold features are within design tolerances is determined. When the dimensions of the patterned mold features are not within the design tolerances: adjusting one or more parameters of the photolithographic operations, forming another replica mold having patterned mold features on the substrate using second photolithographic operations at the adjusted parameters, and determining whether dimensions of patterned mold on the substrate of the another replica mold are within the design tolerances. When the dimensions of the patterned mold features are within the design tolerances: contacting the patterned mold with a resist layer disposed over a replica blank, exposing the resist layer to a first actinic radiation, separating the patterned mold and the exposed resist layer, wherein a pattern is formed in the exposed resist layer, extending the pattern in the resist layer into the replica blank, and removing the resist layer from the replica blank to form a replica. In an embodiment, the substrate includes a target layer disposed over a wafer. In an embodiment, the wafer is a silicon wafer, and the target layer includes one or more materials selected from the group consisting of a silicon oxide, a silicon nitride, carbon, SiOC, SiON, SiOCN, a metal, a metal oxide, and ultraviolet radiation absorbing organic compounds. In an embodiment, the replica blank is made of fused silica. In an embodiment, during the exposing the resist layer to the first actinic radiation, the actinic radiation passes through the replica blank to expose the resist layer. In an embodiment, during the first photolithographic operation: a second actinic radiation is directed towards a photomask including photomask pattern features corresponding to the mold features, and dimensions of the mold features are smaller than the corresponding photomask pattern features. In an embodiment, dimensions of the mold features are 2 to 10 times smaller than the corresponding photomask pattern features. In an embodiment, the second actinic radiation is deep ultraviolet radiation or extreme ultraviolet radiation. In an embodiment, the first actinic radiation is ultraviolet radiation. In an embodiment, exposing the resist layer to a first actinic radiation hardens exposed portions of the resist layer.

Another embodiment of the disclosure is a method of manufacturing a semiconductor device, including photolithographically patterning a first resist layer disposed over a first substrate. The photolithographically patterning is performed using a photomask. A pattern formed in the first resist layer is extended into the substrate to form a patterned mold in the substrate. The patterned mold is inspected, and whether dimensions of the patterned mold are within design tolerances is determined. The patterned mold is contacted with a second resist layer disposed over a replica blank when the dimensions of the patterned mold are within the design tolerances. The second resist layer is exposed to a first actinic radiation, wherein portions of the second resist layer are hardened by exposure to the first actinic radiation. The replica blank is etched using the hardened second resist layer as a mask. The second resist layer is removed from the replica blank to form a replica. A third resist layer is deposited over a second substrate. The replica is contacted with the third resist layer. The third resist layer is exposed to a second actinic radiation passing through the replica to form a pattern in the third resist layer. The exposing the third resist layer to actinic radiation hardens exposed portions of the third resist layer. The pattern in the third resist layer is transferred into the second substrate. In an embodiment, the depositing the third resist layer over the second substrate includes ejecting droplets of a third resist layer material from an inkjet printer over the substrate. In an embodiment, the first substrate is made of one or more materials selected from the group consisting of silicon, a silicon oxide, a silicon nitride, carbon, SiOC, SiON, SiOCN, a metal, a metal oxide, and an ultraviolet radiation organic compound. In an embodiment, the second substrate includes a silicon wafer. In an embodiment, the replica blank is made of fused silica.

Another embodiment of the disclosure is a method of manufacturing a semiconductor device, including using photolithography operations to form a plurality of molds on a first substrate. The plurality of molds are inspected for defects, and which of the plurality of molds have defect levels below a threshold level is determined. One or more replicas are formed using one or more of the plurality of molds having defect levels below the threshold level. A resist layer is formed over a second substrate, and the one or more plurality of molds having defect levels below the threshold level are used to form one or more patterns in the resist layer. In an embodiment, during the photolithography operations: actinic radiation is directed towards a photomask including one or more photomask pattern features, and one or more mold features are formed in each of the plurality of molds corresponding to the one or more pattern features, wherein dimensions of the one or mold features are smaller than the corresponding one or more pattern features. In an embodiment, dimensions of the one or more mold features are 2 to 10 times smaller than the corresponding one or more pattern features. In an embodiment, the actinic radiation is deep ultraviolet radiation or extreme ultraviolet radiation. In an embodiment, the first and second substrates include silicon wafers.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a nanoimprint lithography replica, comprising:
depositing a first resist layer over a substrate;
selectively exposing the first resist layer to a first actinic radiation;
developing the selectively exposed first resist layer to form a pattern in the first resist layer;
extending the pattern in the first resist layer into the substrate to form a mold in the substrate;
removing the first resist layer from the substrate;
depositing a second resist layer over a replica blank;
contacting the second resist layer with the mold;
exposing the second resist layer to a second actinic radiation;
separating the mold and the exposed second resist layer,
wherein a pattern is formed in the exposed second resist layer;
extending the pattern in the second resist layer into the replica blank; and
removing the second resist layer from the replica blank to form a replica.

2. The method according to claim 1, wherein the selectively exposing the first resist layer to a first actinic radiation includes directing the first actinic radiation towards a photomask.

3. The method according to claim 1, wherein the first actinic radiation is deep ultraviolet or extreme ultraviolet radiation.

4. The method according to claim 1, wherein the exposing the second resist layer to the second actinic radiation hardens exposed portions of the second resist layer.

5. The method according to claim 1, wherein the second actinic radiation is ultraviolet radiation.

6. The method according to claim 1, wherein the depositing the second resist layer over a replica blank comprises ejecting droplets of a second resist layer material from an inkjet printer over the replica blank.

7. The method according to claim 1, wherein during the exposing the second resist layer to the second actinic radiation, the second actinic radiation passes through the replica blank to expose the second resist layer.

8. The method according to claim 1, wherein the substrate is made of one or more materials selected from the group consisting of silicon, a silicon oxide, a silicon nitride, carbon, SiOC, SiON, SiOCN, a metal, a metal oxide, and an ultraviolet radiation organic compound.

9. The method according to claim 8, wherein the substrate includes a silicon wafer.

10. The method according to claim 1, wherein the replica blank is made of fused silica.

11. A method of manufacturing a nanoimprint lithography replica, comprising:
depositing a first resist layer over a substrate;
exposing the first resist layer to a first patterned actinic radiation,
wherein the first patterned actinic radiation is patterned by a photomask;
developing the exposed first resist layer to form a pattern in the first resist layer;
extending the pattern in the first resist layer into the substrate to form a patterned mold in the substrate;
inspecting the patterned mold;
determining whether dimensions of the patterned mold are within design parameters;
contacting the patterned mold with a second resist layer disposed over a replica blank when the dimensions of the patterned mold are within the design parameters;
exposing the second resist layer to a second actinic radiation;
separating the mold and the exposed second resist layer,
wherein a pattern is formed in the exposed second resist layer;
extending the pattern in the second resist layer into the replica blank; and
removing the second resist layer from the replica blank to form a replica.

12. The method according to claim 11, wherein the substrate comprises a target layer disposed over a wafer.

13. The method according to claim 12, wherein:
the wafer is a silicon wafer, and
the target layer comprises one or more materials selected from the group consisting of a silicon oxide, a silicon nitride, carbon, SiOC, SiON, SiOCN, a metal, a metal oxide, and ultraviolet radiation absorbing organic compounds.

14. The method according to claim 11, wherein the replica blank is made of fused silica.

15. The method according to claim 11, wherein during the exposing the second resist layer to the second actinic radiation, the second actinic radiation passes through the replica blank to expose the second resist layer.

16. A method of manufacturing a semiconductor device, comprising:
using photolithography operations to form a mold on a first substrate;
depositing a first resist layer over a replica blank;
contacting the first resist layer with the mold;
exposing the first resist layer to a first actinic radiation passing through the replica blank to form a pattern in the first resist layer,
wherein the exposing the first resist layer to the first actinic radiation hardens exposed portions of the first resist layer;
transferring the pattern in the first resist layer into the replica blank to form a replica;
depositing a second resist layer over a second substrate;
contacting the replica with the second resist layer;
exposing the second resist layer to a second actinic radiation passing through the replica to form a pattern in the second resist layer,
wherein the exposing the second resist layer to actinic radiation hardens exposed portions of the second resist layer; and
transferring the pattern in the second resist layer into the second substrate.

17. The method according to claim 16, wherein during the photolithography operations:
a third actinic radiation is directed towards a photomask including one or more pattern features; and
one or more mold features are formed in the mold corresponding to the one or more pattern features,
wherein dimensions of the one or mold features are smaller than the corresponding one or more pattern features.

18. The method according to claim 17, wherein dimensions of the one or more mold features are 2 to 10 times smaller than the corresponding one or more pattern features.

19. The method according to claim 17, wherein the third actinic radiation is deep ultraviolet radiation or extreme ultraviolet radiation.

20. The method according to claim 16, wherein the first and second substrates comprise silicon wafers.
